(19) United States
(12) Patent Application Publication
(10) Pub. No.: US 2011/0291646 A1
(43) Pub. Date: Dec. 1, 2011

(54) ORIGIN POSITION SIGNAL DETECTOR

(75) Inventors: Takeshi Musha, Chiyoda-ku (JP); Hiroshi Nishizawa, Chiyoda-ku (JP); Hajime Nakajima, Chiyoda-ku (JP); Yoichi Omura, Chiyoda-ku (JP); Koichi Takamune, Chiyoda-ku (JP); Norio Takamune, Kumamoto (JP)

(73) Assignee: MITSUBISHI ELECTRIC CORPORATION, Chiyoda-ku, Tokyo (JP)

(21) Appl. No.: 12/933,319

(22) PCT Filed: Feb. 25, 2009
(86) PCT No.: PCT/JP2009/053362

§ 371 Date: Jan. 7, 2011

(30) Foreign Application Priority Data
Mar. 17, 2008 (JP) 2008-067536

(51) Int. Cl. G01R 33/00

(52) U.S. Cl. 324/207.11

(57) ABSTRACT

An origin position signal detector comprising: a rotary or linear scale (1) which includes an incremental track (3) magnetized at equal intervals and an origin position detection track (4) for detecting an origin position, and a magnetic sensor (5) which detects magnetic fields from the scale. The origin position detection track includes an origin position magnetized portion (11) and side magnetized portions (12) provided on both sides of the origin position magnetized portion (11) and magnetized with magnetization in the same direction at one or more positions as the origin position magnetized portion (11).

### TECHNICAL FIELD

The present invention relates to an origin position signal detector capable of detecting an origin position in magnetic rotational angle sensors such as magnetic rotary encoders and magnetic position detectors such as magnetic linear encoders.

### BACKGROUND ART

A magnetic rotational angle sensor is known as an example in which a typical origin position signal detector is used. This magnetic rotational angle sensor is roughly provided with a rotary drum that is mounted to a rotary shaft of a motor and such, for example, and changes the generated magnetic field according to its rotation, and a magnetism detecting sensor that detects the varying magnetic field (Patent Document 1, for example).

Magnets are provided along an outer circumferential surface of the rotary drum by such as application, fitting, and adhesion. Its detection tracks include an incremental track for detecting a rotational angle of the rotary drum and an origin position detection track for detecting an origin position for detecting the rotational angle.

The incremental track is magnetized at regular intervals of a pitch P along a circumstance of the rotary drum, the pitch P is defined by a relation of P=360°/W, where W is a wave number in a single rotation required for detecting an incremental signal. Further, the origin position detection track is magnetized at only one portion along the circumstance such that a single pulse waveform is generated in a single rotation of the rotary drum. A width of the magnetization of the origin position detection track is suitably set according to a method of signal processing.

The magnetism detecting sensor is configured, according to the magnetization of the incremental track and the origin position detection track of the rotary drum, by a plurality of magnetoresistance elements or an array of magnetoresistance elements such as anisotropic magnetoresistive (AMR) elements and giant magnetoresistive (GMR) elements, and is disposed at a given interval away from the rotary drum.

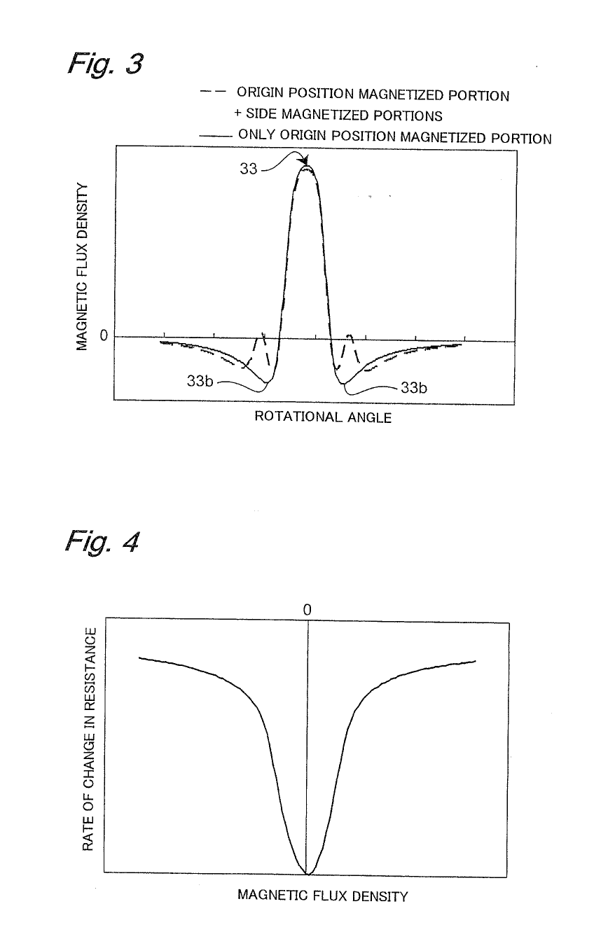

According to a common method of processing origin position detection signals for the conventional magnetic rotational angle sensor thus configured, as shown in FIG. 3 of the Patent Document 1, analog signals outputted from the magnetoresistance elements are converted into pulse waveforms by the threshold voltage, and a converted signal is taken as an origin position detection signal.

Patent Document 1: Japanese Unexamined Patent Application Publication No. H05-223592 (Japanese Patent No. 3195019)

### DISCLOSURE OF THE INVENTION

### Subject to be solved by the Invention

Commonly used magnetoresistance elements as a magnetism detecting sensor such as AMR and GMR elements have physical characteristics that outputs from the elements decrease as the temperature increases. For example, as an output from the AMR element generally decreases at a rate of 0.3-0.5%/° C., for example, when ambient temperature rises from 20° C. up to 80° C., an output of the origin position detection signal decreases by 15% to 25%. Accordingly, it is necessary to set the threshold voltage for generating the origin position detection signal as low as possible, considering the case of high temperatures. In addition, the origin position detection signal increases or decreases due to factors such as an assembly error of the magnetism detecting sensor with respect to the rotary drum. Therefore, it is also necessary to set the threshold voltage sufficiently low in the context of the above situation.

On the other hand, the analog signals outputted from the magnetoresistance elements include small peaks respectively on both sides of a large peak, as shown in FIG. 3 and FIG. 4 of the Patent Document 1 (the small peaks are hereinafter referred to as the “side peaks”). Therefore, in order to prevent the side peak from being falsely identified as an origin position detection signal, the threshold voltage cannot be set lower than the height of the side peak. There are also variations of the height in the side peak due to the setting error of the threshold voltage and the assembly error of the magnetism detecting sensor as described above. Therefore, taking the side peaks into consideration, the threshold voltage is required to be set sufficiently high by adding an extra to the height of the side peaks. Consequently, it is practically impossible to set the designed threshold voltage to be extremely low.

Moreover, as outputs from the AMR and GMR elements increase when the temperature is low, an output value in the side peak is increased. Therefore, when the output in the side peak exceeds the threshold voltage that has been set, the origin position signal detector possibly detects the side peak, resulting in false detection of the origin position.

As can be seen from the above situations, in order to realize stable origin position signal detection, it is important to suppress the output of the side peak as low as possible.

The present invention is contrived in order to address the above problem, and an object of the present invention is to provide an origin position signal detector capable of detecting a signal for detecting an origin position of a magnetic encoder more stably as compared to the conventional detector.

### Means for Solving the Problem

In order to achieve the above object, the present invention is configured as described in the following.

That is, an origin position signal detector according to one aspect of the present invention is provided with a detection target member which includes an incremental track and an origin position detection track, and a magnetic sensor configured to detect magnetic fields in the incremental track and the origin position detection track, the incremental track having displacement detection magnetized portions magnetized at equal intervals along a displacement direction for detecting a displacement amount, the origin position detection track having an origin position magnetized portion for detecting an origin position for the detection of the displacement amount;

the origin position detection track further including side magnetized portions on both sides of the origin position magnetized portion in the displacement direction, the side magnetized portions being magnetized with magnetization in the same direction as the origin position magnetized portion.

The side magnetized portion may be disposed on each side of the origin position magnetized portion with an equal number or may be disposed away from the origin position magnetized portion via a specific gap.

The origin position magnetized portion and the side magnetized portions may be magnetized with magnetization currents of the same intensity or may be magnetized with magnetization currents of different intensities.

The side magnetized portions may be configured such that a magnetization width of each side magnetized portion decreases as a distance from the origin position magnetized portion increases.

The origin position magnetized portion and the side magnetized portions may be magnetized at relative positions at which an influence to the magnetization of the incremental track is eliminated.

### Effects of the invention

According to the origin position signal detector of the one aspect of the present invention, providing the side magnetized portions on both sides of the origin position magnetized portion allows the origin position detection track to lower the output value of the side peak that is associated with the analog signal outputted from the magnetic sensor. Thus, a threshold voltage for generating an origin position detection signal can be set lower. As a result, it is possible to improve stability in detection of the origin position detection signal when the temperature is high, as well as to reduce false detection of the origin position detection signal due to the side peak exceeding the preset threshold voltage when the temperature is low. Consequently, according to the origin position signal detector of the one aspect of the present invention, it is possible to detect the origin position detection signal in the magnetic encoder with greater stability as compared to the conventional example.

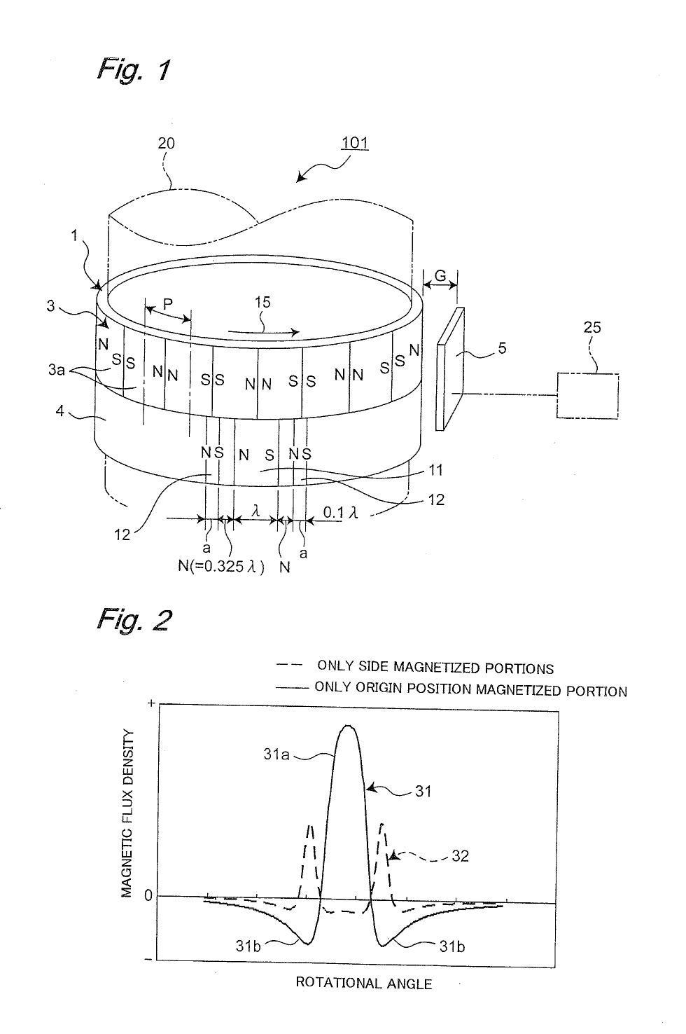

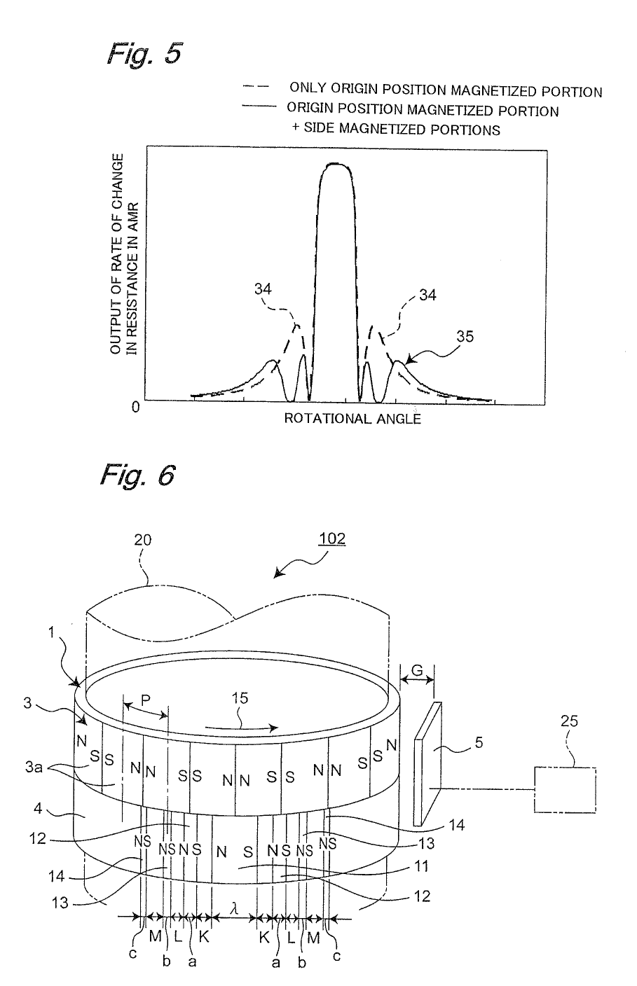

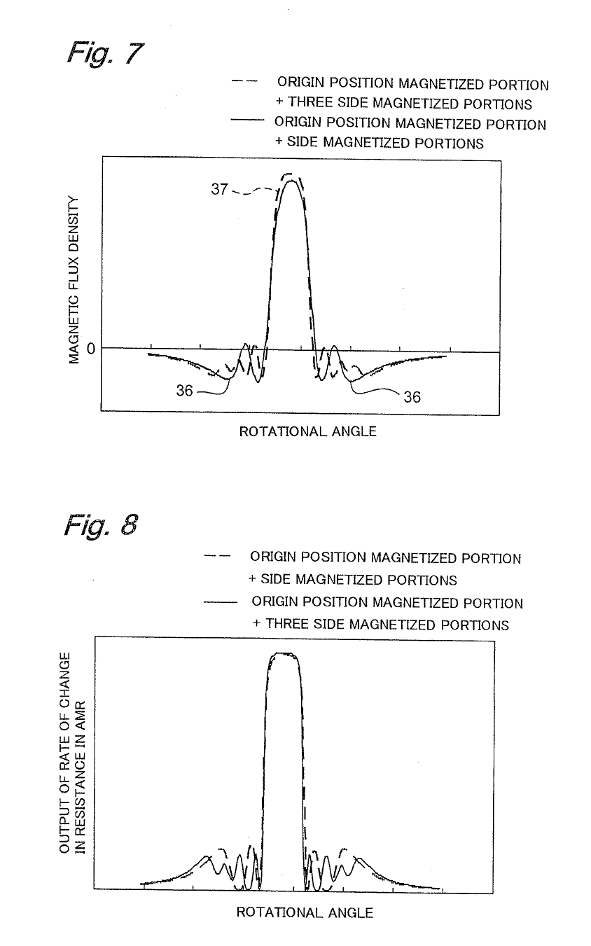

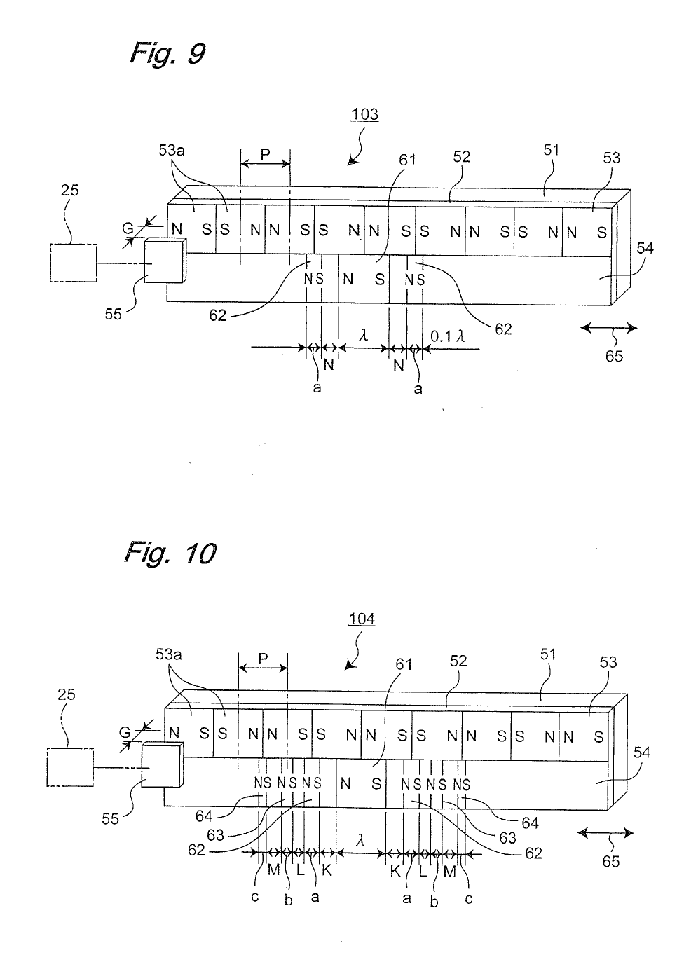

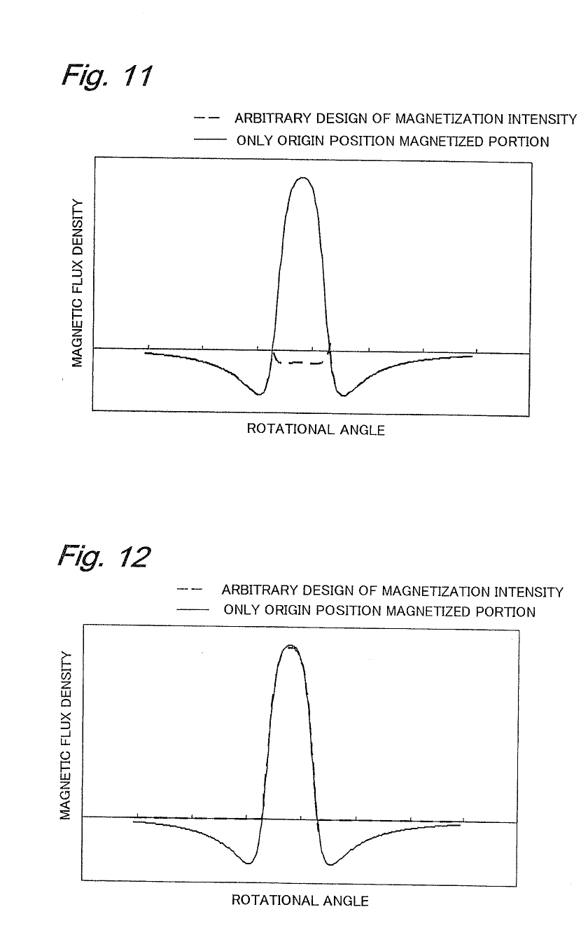

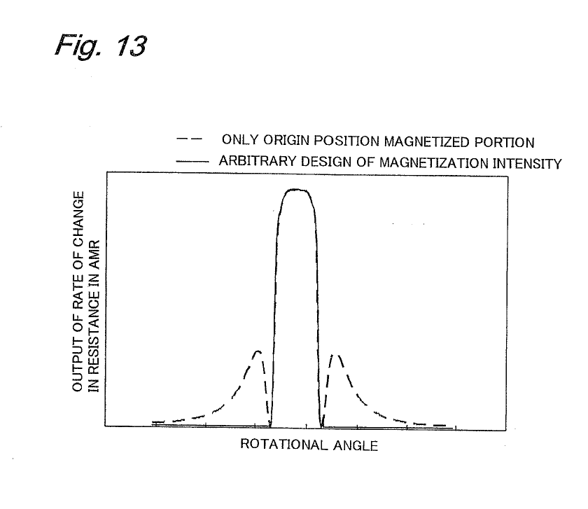

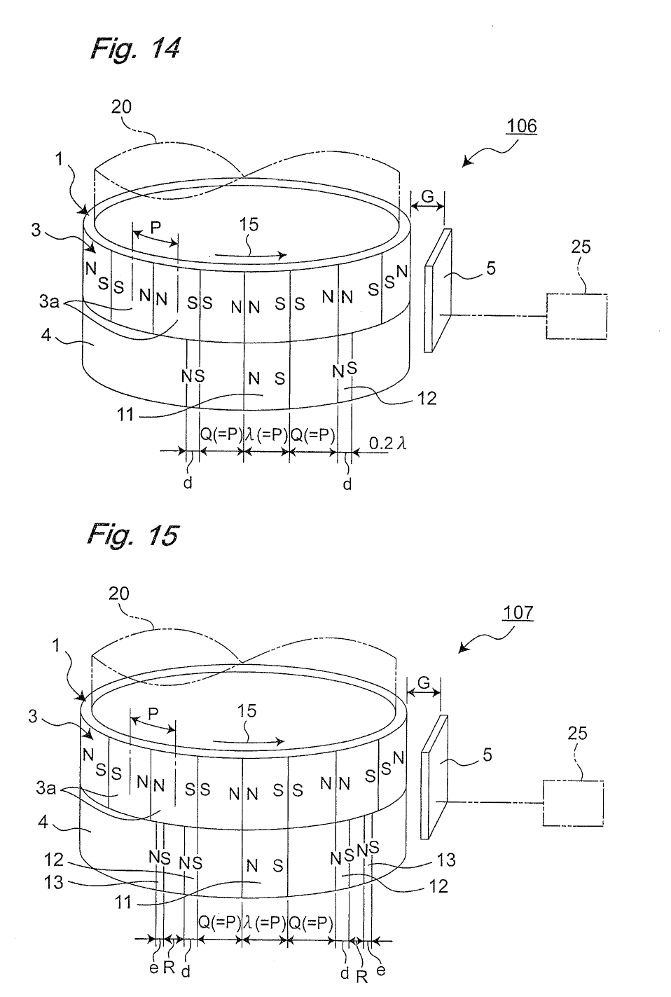

### BRIEF DESCRIPTION OF THE DRAWINGS

[FIG. 1] FIG. 1 is a perspective view illustrating a schematic configuration of a magnetic rotational angle sensor according to an embodiment 1 of the present invention.

[FIG. 2] FIG. 2 is a graphical chart showing simulation of a time change in distribution of magnetic flux density in a surface of a magnetoresistance element only by an origin position magnetized portion, and a time change in distribution of magnetic flux density in the surface of the magnetoresistance element only by side magnetized portions, respectively due to the rotation of a rotary drum in the magnetic rotational angle sensor shown in FIG. 1.

[FIG. 3] FIG. 3 is a graphical chart showing simulation of the time change in distribution of magnetic flux density in the surface of the magnetoresistance element only by the origin position magnetized portion, and a time change in distribution of magnetic flux density in the surface of the magnetoresistance element by both the origin position magnetized portion and the side magnetized portions, in the magnetic rotational angle sensor shown in FIG. 1.

[FIG. 4] FIG. 4 is a graphical chart showing a typical sensitivity curve of an AMR element as a common magnetoresistance element.

[FIG. 5] FIG. 5 is a graphical chart converted to a rate of change in resistance of the AMR element due to the rotation of the rotary drum obtained by applying the change in the magnetic flux density distribution shown in FIG. 3 to the sensitivity curve of the AMR element shown in FIG. 4.

[FIG. 6] FIG. 6 is a perspective view illustrating a schematic configuration of a magnetic rotational angle sensor according to an embodiment 2 of the present invention.

[FIG. 7] FIG. 7 is a graphical chart showing simulation of the time change in distribution of magnetic flux density in the surface of the magnetoresistance element by both the origin position magnetized portion and the side magnetized portions shown in FIG. 3, and a time change in distribution of magnetic flux density in a surface of a magnetoresistance element by all of an origin position magnetized portion and three side magnetized portions in the magnetic rotational angle sensor shown in FIG. 6.

[FIG. 8] FIG. 8 is a graphical chart converted to a rate of change in resistance of the AMR element due to the rotation of the rotary drum obtained by applying the change in the magnetic flux density distribution shown in FIG. 7 to the sensitivity curve of the AMR element shown in FIG. 4.

[FIG. 9] FIG. 9 is a perspective view illustrating a schematic configuration of a magnetic position detection sensor according to an embodiment 3 of the present invention.

[FIG. 10] FIG. 10 is a perspective view illustrating a schematic configuration of a magnetic position detection sensor according to an embodiment 4 of the present invention.

[FIG. 11] FIG. 11 is a graphical chart showing simulation of a time change in distribution of magnetic flux density in a surface of a magnetoresistance element by an individual magnetized portion when an origin position magnetized portion and side magnetized portions are separately magnetized, according to an embodiment 5 of the present invention.

[FIG. 12] FIG. 12 is a graphical chart showing simulation of a time change in distribution of magnetic flux density in a surface of a magnetoresistance element by both of the origin position magnetized portion and the side magnetized portions when the origin position magnetized portion and the side magnetized portions are separately magnetized, according to the embodiment 5 of the present invention.

[FIG. 13] FIG. 13 is a graphical chart converted to a rate of change in resistance of the AMR element due to the rotation of the rotary drum obtained by applying the change in the magnetic flux density distribution shown in FIG. 12 to the sensitivity curve of the AMR element shown in FIG. 4, according to the embodiment 5 of the present invention.

[FIG. 14] FIG. 14 is a perspective view illustrating a schematic configuration of a magnetic position detection sensor according to an embodiment 6 of the present invention.

[FIG. 15] FIG. 15 is a perspective view illustrating a schematic configuration of a variation of the magnetic position detection sensor shown in FIG. 14.

### EXPLANATION OF THE REFERENCE NUMERALS

1 Detection Target Member
3 Incremental Track
3a Displacement Detection Magnetized portion
4 Origin Position Detection Track
5 Magnetoresistance Element
11 Origin Position Magnetized portion
12, 13, 14 Side Magnetized portions
15 Rotational Direction
20 Rotary Drum
34 Side Peak
52 Detection Target Member
53 Incremental Track
53a Displacement Detection Magnetized portion
54 Origin Position Detection Track
55 Magnetoresistance Element
61 Origin Position Magnetized portion
62, 63, 64 Side Magnetized portions
65 Direct Acting Direction
101-104, 106, 107 Origin Position Signal Detectors

### BEST MODE FOR CARRYING OUT THE INVENTION

Origin position signal detectors according to embodiments of the present invention will be hereinafter described with reference to the drawings. It should be noted that like or the same components are denoted by like or the same reference numerals throughout the drawings.

### Embodiment 1

The following describes an origin position signal detector according to an embodiment 1 of the present invention with reference to FIG. 1 to FIG. 5.

FIG. 1 shows a schematic configuration of an origin position signal detector 101 according to this embodiment, the detector serving as a magnetic rotational angle sensor among magnetic rotary encoders. The origin position signal detector 101 roughly has a detection target member 1 and a magnetoresistance element 5 as an example that serves a function of a magnetic sensor.

The detection target member 1 is a magnet that is attached along an outer circumferential surface of a rotary drum 20 that corresponds to a rotary shaft of a motor and the like, for example, by means of application, fitting, adhesion, and such. In the detection target member 1, an incremental track 3 and an origin position detection track 4 are arranged in a two-tiered manner in an axial direction of the rotary drum 20.

In order to detect a displacement amount, the incremental track 3 has displacement detection magnetized portions 3a that are alternately magnetized at equal intervals in a displacement direction so as to correspond to a magnetization direction of S pole→N pole and N pole t→S pole, or a direction from left to right in the drawing. In this embodiment, the displacement amount corresponds to a rotational angle, and the displacement direction corresponds to a rotational direction 15 of the detection target member 1. Thus, the displacement detection magnetized portions 3a are magnetized at equal intervals of a pitch P in the rotational direction 15 along an entire circumference of the incremental track 3. The pitch P is defined by a relation of P=360°/W, where W is a wave number within a single rotation required for detecting an incremental signal.

The origin position detection track 4 has an origin position magnetized portion 11 and side magnetized portions 12.

The origin position magnetized portion 11 is a magnetized portion for detecting an origin position in detecting the displacement amount, that is, in detecting a rotational angle of the detection target member 1 in this embodiment. Further, the origin position magnetized portion 11 is formed at a single location of the origin position detection track 4 with a magnetization width λ in the rotational direction 15 such that a single pulse waveform is generated for one rotation of the detection target member 1. The magnetization width λ of the origin position magnetized portion 11 is provided with a given magnetization width with respect to the magnetization pitch P of the incremental track 3, such as λ=P or λ=2P, for example.

The side magnetized portions 12 are arranged respectively on both sides of the origin position magnetized portion 11 in the rotational direction 15, each side magnetized portion 12 is magnetized with magnetization in the same direction as the origin position magnetized portion 11 along the rotational direction 15. Further, in this embodiment, each of the side magnetized portions 12 has a width “a” of 0.1λ and is positioned away from the origin position magnetized portion 11 via a gap “N” of 0.325λ (where λ is the magnetization width of the origin position magnetized portion 11) in the rotational direction 15.

The magnetoresistance element 5 is for detecting magnetic fields of the incremental track 3 and the origin position detection track 4, and is configured by a plurality of magnetoresistance elements or magnetoresistance element array including such as a plurality of AMR elements (anisotropic magnetoresistance elements) or GMR elements (giant magnetoresistance elements) according to the magnetization of the incremental track 3 and the origin position detection track 4. The magnetoresistance element 5 is spaced with a specific interval G from the detection target member 1 in a diametrical direction of the detection target member 1.

An operation of the origin position signal detector 101 thus configured is described in the following. It should be noted that the magnetoresistance element 5 is connected with a signal processing circuit 25 that processes an analog signal outputted from the magnetoresistance element 5 and outputs a signal corresponding to a rotational angle of the detection target member 1.

For example, by rotation of the detection target member 1 attached to an output shaft of the motor, the magnetoresistance element 5 detects respective changes in magnetic fields of the displacement detection magnetized portions 3a on the incremental track 3, and the origin position magnetized portion 11 and the side magnetized portions 12 on the origin position detection track 4.

FIG. 2 is a graphical chart showing simulation of a time change in distribution of magnetic flux density in the magnetoresistance element 5 in a state that the magnetic fields of the origin position magnetized portion 11 and the side magnetized portions 12 separately act upon a surface of the magnetoresistance element 5. A solid line 31 shown in FIG. 2 represents the magnetic flux density distribution (vertical axis) only in the origin position magnetized portion 11 in relation to the rotational angles (horizontal axis) of the rotary drum 20. A dotted line 32 shown in FIG. 2 represents the magnetic flux density distribution (vertical axis) only in the side magnetized portions 12 in relation to the rotational angles (horizontal axis) of the rotary drum 20. Further, FIG. 3 is a graphical chart showing simulation of a time change in distribution of magnetic flux density in the magnetoresistance element 5 in a state that the magnetic fields of the origin position magnetized portion 11 and the side magnetized portions 12 both act upon the surface of the magnetoresistance element 5. A solid line 33 shown in FIG. 3 represents the magnetic flux density distribution (vertical axis) only in the origin position magnetized portion 11 in relation to the rotational angles (horizontal axis) of the rotary drum 20. A dotted line shown in FIG. 3 represents the magnetic flux density distribution (vertical axis), when both of the origin position magnetized portion 11 and the side magnetized portions 12 act, in relation to the rotational angles (horizontal axis) of the rotary drum 20. Moreover, FIG. 4 shows a typical example of a sensitivity curve of the AMR element as a common magnetoresistance element. Further, FIG. 5 shows a graphical chart converted to a rate of change in resistance of the AMR element due to the rotation of the rotary drum in a state applying the change in the magnetic flux density distribution shown in FIG. 3 to the sensitivity curve of the AMR element shown in FIG. 4. Referring to FIG. 5, a solid line indicates the change in the rate of change in resistance due to both of the origin position magnetized portion 11 and the side magnetized portions 12, and a dotted line indicates the change in the rate of change in resistance only due to the origin position magnetized portion 11.

As shown in FIG. 2, the solid line 31 indicating the change in the magnetic flux density only due to the origin position magnetized portion 11 shows a waveform including a main pulse waveform 31a that extends in a positive direction of the vertical axis and sub pulse waveforms 31b that extend in a negative direction on the right and left sides of the main pulse waveform 31a. The formation of such a waveform can be physically caused by the concentration of the magnetic flux generated around the magnetized portion in the configuration that only one polarity is magnetized within one rotation of the rotary drum. On the other hand, the magnetoresistance element 5 shows output characteristics similar to an even function with respect to the positive and negative of the magnetic flux density as shown in FIG. 4. Therefore, each of portions 33b in FIG. 3 which extends in the negative direction forms a waveform with a large peak in the positive direction, that is, a side peak 34 in the output of the magnetoresistance element 5 as shown by the dotted line in FIG. 5.

On the other hand, as shown by the dotted line 32 in FIG. 2, the magnetic flux density distribution produced by the side magnetized portion 12 on the surface of the magnetoresistance element 5 exactly shows the magnetic flux density distribution which cancels the sub pulse waveform 31b extending to the negative direction in the solid line 31. Therefore, as shown by the solid line 33 in FIG. 3, the magnetic flux density distribution generated on the surface of the magnetoresistance element 5 by the origin position detection track 4 having the origin position magnetized portion 11 and side magnetized portions 12 shows the magnetic flux density distribution in which the portions 33b extending in the negative direction is partially cancelled. As a result, as shown by the solid line 35 in FIG. 5, the output of the magnetoresistance element 5 shows a waveform in which side peaks 34 are lowered.

In this manner, it is possible to obtain a waveform in which the side peaks 34 are lowered and which is outputted from the magnetoresistance element 5 by providing the side magnetized portions 12 on the both sides of the origin position magnetized portion 11. Thus, a threshold voltage for generating an origin position detection signal can be set lower. As a result, it is possible to improve stability in detection of the origin position detection signal when the temperature is high, as well as to reduce false detection of the origin position detection signal due to the side peak exceeding the preset threshold voltage when the temperature is low. Consequently, it is possible to detect the origin position detection signal in the magnetic encoder with greater stability as compared to the conventional example.

According to this embodiment, in one example, the side magnetized portions 12 are arranged with but not limited to the dimensions where the gap “N” is 0.325λ and the width “a” is 0.1λ. Specifically, the arrangement of the side magnetized portions 12 can be designed as suited depending on such as magnetic characteristics of the detection target member 1 and a value of the magnetization width λ of the origin position magnetized portion 11.

Further, FIG. 2, FIG. 3, and FIG. 5 show simulations of the cases in which the origin position magnetized portion 11 and the side magnetized portions 12 are magnetized with magnetization currents of the same intensity up to saturation magnetic flux density of the magnets. As just described, with the method of magnetizing the origin position magnetized portion 11 and the side magnetized portions 12 with magnetization currents of the same intensity up to saturation magnetic flux density of the magnets, as saturated magnetization values can be made constant, it is possible to provide advantageous effects that variation in magnetization intensity in mass production can be reduced and origin position signal detectors with stable quality can be provided.

However, this embodiment is not limited to the method of magnetizing the origin position magnetized portion 11 and the side magnetized portions 12 with magnetization currents of the same intensity up to saturation magnetic flux density of the magnets. Specifically, a level of magnetization after the magnetized portions are magnetized can be arbitrarily set depending on such as magnetic characteristics of the detection target member 1. It is even possible to completely eliminate the side peaks 34 in the output waveform of the magnetoresistance element 5 by magnetizing the origin position magnetized portion 11 and the side magnetized portions 12 respectively with magnetization currents of different intensities. This is detailed in an embodiment 5 that will be described later.

Further, this embodiment describes the example in which the origin position magnetized portion 11 and the side magnetized portions 12 are magnetized to the detection target member 1. However, the present invention is not limited to this example, and the side magnetized portions can be, for example, configured by arranging already magnetized magnets with respect to the origin position magnetized portion 11 afterwards by means of adhesion and such.

### Embodiment 2

An embodiment 2 according to the present invention will be now described with reference to FIG. 6 to FIG. 8.

Here, FIG. 6 shows a schematic configuration of an origin position signal detector 102 according to the embodiment 2 of the present invention. FIG. 7 shows, by comparison, the results of the simulation of the time change in distribution of magnetic flux density of the magnetoresistance element in the origin position signal detector 101 according to the embodiment 1, and results of simulation of a time change in distribution of magnetic flux density of a magnetoresistance element in the origin position signal detector 102 according to the embodiment 2. It should be noted that, in FIG. 7, a solid line represents the case of the origin position signal detector 101, and a dotted line represents the case of the origin position signal detector 102. FIG. 8 shows a chart converted to a rate of change in resistance of the AMR element due to the rotation of the rotary drum in a state applying the change in the magnetic flux density distribution shown in FIG. 7 to the sensitivity curve of the AMR element shown in FIG. 4. It should be noted that a solid line represents the case of the origin position signal detector 102, and a dotted line represents the case of the origin position signal detector 101.

In the origin position signal detector 101 according to the embodiment 1 as described above, the side magnetized portion 12 is disposed at a single location on one side of the origin position magnetized portion 11. However, in the origin position signal detector 102 according to the embodiment 2, the side magnetized portions are disposed at a plurality of locations on one side of the origin position magnetized portion 11. In this regard, the origin position signal detector 101 and the origin position signal detector 102 are different, and the configuration of the origin position signal detector 102 is the same as the configurations of the origin position signal detector 101 except for the above difference. Therefore, the following only describes the difference in the configuration.

According to the origin position signal detector 102, in order to generate a single pulse waveform for one rotation of the rotary drum 20, the origin position detection track 4 has the origin position magnetized portion 11 with the magnetization width λ at a single location, and the side magnetized portions 12 and side magnetized portions 13 and 14 in the magnetization direction that is the same as the origin position magnetized portion 11 at three locations on each side of the origin position magnetized portion 11.

The side magnetized portion 12 has the width “a” of 0.1λ and is positioned away from the origin position magnetized portion 11 via a gap “K” of 0.34λ (where λ is the magnetization width of the origin position magnetized portion 11) in the rotational direction 15.

The side magnetized portion 13 has a width “b” of 0.05λ and is positioned away from the side magnetized portion 12 via a gap “L” of 0.325λ in the rotational direction 15.

The side magnetized portion 14 has a width “c” of 0.025λ and is positioned away from the side magnetized portion 13 via a gap “M” of 0.3λ in the rotational direction 15.

As described above, as the distance from the origin position magnetized portion 11 increases, the gaps “K”, “L”, and “M” between the magnetized portions gradually decrease and the widths “a”, “b”, and “c” respectively of the side magnetized portions 12, 13, and 14 in the rotational direction 15 also decrease. It should be noted that the relation between the distance from the origin position magnetized portion 11 and magnetization width of the side magnetized portion is not limited to the case in which the plurality of the side magnetized portions 12-14 are arranged as this embodiment. Even when a single side magnetized portion is disposed on one side of the origin position magnetized portion 11, the magnetization width of the side magnetized portion decreases as the distance from the origin position magnetized portion 11 becomes larger.

According to the origin position signal detector 102 of this embodiment having the above described configuration, similar to the origin position signal detector 101 as previously described, it is possible to obtain a waveform in which the side peaks 34 are lowered and that is outputted from the magnetoresistance element 5.

Moreover, providing the side magnetized portions 12, 13, and 14 on each side of the origin position magnetized portion 11 further provides the following advantageous effect as compared to the first embodiment.

Specifically, the solid line in FIG. 7 indicates the magnetic flux density distribution in the magnetoresistance element 5 according to the embodiment 1, and shows a waveform in which a portion of the waveform that extends in the negative direction is canceled. However, on the left and right sides of the waveforms, there are still peaks 36 slightly extending in the negative direction. In the embodiment 2, the side magnetized portions 13 and 14 are provided so that these peaks 36 can be canceled.

Therefore, the magnetic flux density distribution, which is indicated by the dotted line 37 in FIG. 7, in the magnetoresistance element 5 according to the embodiment 2 shows a form in which the output of the magnetic flux density distribution corresponding to the peaks 36 is lowered as compared to the embodiment 1. This can be also seen from FIG. 8, and as compared to the AMR output in the configuration of the embodiment 1 indicated by the dotted line, the output of this embodiment indicated by the solid line shows the waveform whose side peaks are slightly lowered.

Thus, according to the embodiment 2, as compared to the embodiment 1, it is possible to detect the origin position detection signal in the magnetic encoder more stably.

While the three side magnetized portions 12, 13, and are provided on each side of the origin position magnetized portion 11 in this embodiment, the number of the side magnetized portions is not limited to three and any number of side magnetized portions can be provided on each side of the origin position magnetized portion 11.

Further, the values of the gap “K”, “L”, and “M” and the widths “a”, “b”, and “c” regarding the side magnetized portions 12, 13, and 14 are not limited to the values described above, and for example, it is possible to set the gaps “K”, “L”, and “M” to be the same width, and to set the widths “a”, “b”, and “c” to be the same width. The values of the gaps “K”, “L”, and “M” and the widths “a”, “b”, and “c” regarding the side magnetized portions 12, 13, and 14 can be designed arbitrarily depending on such as the magnetic characteristics of the detection target member 1 and the value of the magnetization width λ of the origin position magnetized portion 11.

Further, FIG. 7 and FIG. 8 show the simulations of the case in which the origin position magnetized portion 11 and the side magnetized portions 12, 13, and 14 are magnetized with the magnetization currents of the same intensity up to the saturation magnetic flux density of the magnets.

However, this embodiment is not limited to such an example, and the level of magnetization after the magnetized portions are magnetized can be arbitrarily set depending on such as magnetic characteristics of the detection target member 1.

Further, this embodiment describes the example in which the origin position magnetized portion 11 and the side magnetized portions 12, 13, and 14 are magnetized to the detection target member 1. However, the side magnetized portions 12, 13, and 14 can be, for example, configured by arranging already magnetized magnets with respect to the origin position magnetized portion 11 afterwards by means of adhesion and such.

### Embodiment 3

An embodiment 3 according to the present invention will be now described with reference to FIG. 9.

An origin position signal detector 103 according to the embodiment 3 is configured such that the configuration of the origin position track according to the embodiment 1 is applied to the magnetic position detection sensor.

FIG. 9 shows a schematic configuration of the origin position signal detector 103 according to this embodiment, the detector serving as a magnetic positional sensor among magnetic linear encoders. The origin position signal detector 103 roughly comprises a detection target member 52 and a magnetoresistance element 55. The detection target member 52 is a plate-like magnet which is attached onto a linear scale plate 51 for example, by means of application, adhesion, and such. Along the detection target member 52, an incremental track 53 and an origin position detection track 54 are provided in a two-tiered manner, and the tracks 53 and 54 extend along a longitudinal direction of the detection target member 52.

In order to detect a displacement amount in a relative direct acting direction of the detection target member 52 and the magnetoresistance element 55, the incremental track 53 has displacement detection magnetized portions 53a which are alternately magnetized at equal intervals such that a magnetization direction of polarities corresponds to S→N and N→S in a displacement direction, or a direction from left to right in the drawing. In this embodiment, the displacement amount corresponds to an amount of linear stroke, and the displacement direction corresponds to a direct acting direction 65 of the detection target member 52. Thus, the displacement detection magnetized portions 53a are magnetized to the incremental track 3 at equal intervals of a pitch P in the direct acting direction 65 along an entire length of the incremental track 3. The pitch P is defined for a stroke S of the direct acting direction 65 by a relation of P=S/W, where W is a wave number required for detecting an incremental signal.

The origin position detection track 54 has an origin position magnetized portion 61 and side magnetized portions 62.

The origin position magnetized portion 61 is a magnetized portion for detecting an origin position in detecting the displacement amount, that is, detecting an amount of stroke of the detection target member 52 in this embodiment. The origin position magnetized portion 61 is provided at a single location in the origin position detection track 54 with a magnetization width λ along the direct acting direction 65 such that a single pulse waveform is generated for a single stroke in one direction of the detection target member 52. Further, the origin position magnetized portion 61 is magnetized with the magnetization in the same direction as the displacement detection magnetized portions 53a in the direct acting direction 65 as shown in FIG. 9. In addition, according to this embodiment, the origin position magnetized portion 61 is provided such that a border between two adjacent displacement detection magnetized portions 53a corresponds to a center or substantially center of the origin position magnetized portion 61 in the direct acting direction 65.

The side magnetized portions 62 are provided respectively on both sides of the origin position magnetized portion 61 in the direct acting direction 65, each side magnetized portion 62 is magnetized with magnetization in the same direction as the origin position magnetized portion 61 in the direct acting direction 65. Further, in this embodiment, each of the side magnetized portions 62 has a width “a” of 0.1λ and is positioned away from the origin position magnetized portion 61 via the gap “N” of 0.325λ (where λ is the magnetization width of the origin position magnetized portion 61) in the direct acting direction 65.

The magnetoresistance element 55 is for detecting magnetic fields in the incremental track 53 and the origin position detection track 54, and is configured by a plurality of magnetoresistance elements or magnetoresistance element array including such as a plurality of AMR elements (anisotropic magnetoresistance elements) or GMR elements (giant magnetoresistance elements) corresponding to the magnetization of the incremental track 53 and the origin position detection track 54. The magnetoresistance element 55 is disposed at a specific interval “G” from the detection target member 52 in a direction orthogonal to the direct acting direction 65.

An operation of the origin position signal detector 103 thus configured is described in the following. It should be noted that the magnetoresistance element 55 is connected with the signal processing circuit 25 that processes an analog signal outputted from the magnetoresistance element 55 and outputs a signal corresponding to the amount of stroke of the detection target member 52.

Similar to what has been described regarding the operation of the origin position signal detector 101 according to the embodiment 1, in the origin position signal detector 103 according to this embodiment, by linear travel of the detection target member 52 in the direct acting direction 65, the magnetoresistance element 55 detects respective changes of magnetic fields of the displacement detection magnetized portions 53a in the incremental track 53, and the origin position magnetized portion 61 and the side magnetized portions 62 in the origin position detection track 54.

In the origin position signal detector 103 according to this embodiment, the origin position detection track 54 is also provided with the origin position magnetized portion 61 and the side magnetized portions 62 on the both sides of the origin position magnetized portion 61. Thus, it is possible to obtain an origin position signal, in which the side peaks 34 are lowered, from the magnetoresistance element 55, similarly to the simulations shown in FIG. 2 to FIG. 5 described in the embodiment 1.

Therefore, the threshold voltage for generating the origin position detection signal can also be set lower in the origin position signal detector 103 according to this embodiment. As a result, it is possible to improve the stability in detection of the origin position detection signal when the temperature is high, as well as to reduce the false detection of the origin position detection signal due to the side peak exceeding the preset threshold voltage when the temperature is low. Consequently, it is possible to detect the origin position detection signal in the magnetic encoder with greater stability as compared to the conventional example.

As have been described in the embodiment 1, the values for the gap “N” and the width “a” regarding the arrangement of the side magnetized portions 62 are not limited to the above described values, but can be designed as suited depending on such as magnetic characteristics of the detection target member 52 and a value of the magnetization width λ of the origin position magnetized portion 61.

Further, a level of magnetization after the origin position magnetized portion 61 and the side magnetized portions 62 are magnetized can be arbitrarily set depending on such as magnetic characteristics of the detection target member 52.

Further, the side magnetized portions 62 can be, for example, configured by applying magnets which have already magnetized with respect to the origin position magnetized portion 61 afterwards by means of adhesion and such.

### Embodiment 4

This embodiment is configured such that the configuration of the origin position track similar to that of the embodiment 2 is applied to the magnetic position detection sensor. An origin position signal detector 104 according to the embodiment 4 will be now described with reference to FIG. 10.

Similar to the relation between the embodiment 1 and the embodiment 2 that has been described previously, in the origin position signal detector 104 according to the embodiment 4, the side magnetized portions are disposed at a plurality of locations on each side of the origin position magnetized portion 61, although the side magnetized portions 62 is disposed at a single location on one side of the origin position magnetized portion 61 in the origin position signal detector 103 according to the embodiment 3. Except for the above difference, the configuration of the origin position signal detector 104 is the same as the configurations of the origin position signal detector 103.

Specifically, according to the origin position signal detector 104 of the embodiment 4, in order to generate a single pulse waveform for a single stroke of the detection target member 52 in one direction, the origin position detection track 54 has the origin position magnetized portion 61 with the magnetization width λ at a single location, and the side magnetized portions 62, 63, and 64 which are magnetized with the magnetization in the same direction as the origin position magnetized portion 61 at three locations on each side of the origin position magnetized portion 61.

The side magnetized portion 62 has the width “a” of 0.1λ and is positioned away from the origin position magnetized portion 61 via a gap “K” of 0.34λ (where λ is the magnetization width of the origin position magnetized portion 61) in the direct acting direction 65.

The side magnetized portion 63 has the width “b” of 0.05λ and is positioned away from the side magnetized portion 62 via a gap “L” of 0.325λ in the direct acting direction 65. The side magnetized portion 64 has the width “c” of 0.025λ and is positioned away from the side magnetized portion 63 via a gap “M” of 0.3λ in the direct acting direction 65.

As described above, as the distance from the origin position magnetized portion 61 increases, the gaps “K”, “L”, and “M” between the magnetized portions gradually decrease and the widths “a”, “b”, and “c” respectively of the side magnetized portions 62, 63, and 64 in the direct acting direction 65 also decrease. It should be noted that, the relation between the distance from the origin position magnetized portion 61 and the magnetization width of the side magnetized portions is not limited to the case in which the plurality of the side magnetized portions 62-64 are provided as in this embodiment. Even when a single side magnetized portion is disposed on one side of the origin position magnetized portion 61, the magnetization width of the side magnetized portion decreases as the distance from the origin position magnetized portion 61 becomes larger.

According to the origin position signal detector 104 of this embodiment having the above described configuration, as in the case of the origin position signal detectors 101, 102, and 103 previously described, it is possible to obtain output waveform in which the side peak 34 is lowered from the magnetoresistance element 55.

Moreover, as described in the second embodiment, providing the side magnetized portions 62, 63, and 64 on each side of the origin position magnetized portion 61 further provides the advantageous effect that it is possible to detect the origin position detection signal in the magnetic encoder more stably as compared to the third embodiment.

Further, the descriptions regarding the variations of the origin position signal detector 102 described in the second embodiment, that is, the number of side magnetized portions, the dimensions of the side magnetized portions, the matters relating to the magnetization of the side magnetized portions, and such can also be applied to the origin position signal detector 104 according to this embodiment.

### Embodiment 5

An embodiment 5 according to the present invention will be now described with reference to FIG. 11 through FIG. 13.

The embodiment 5 can be applied to the origin position signal detectors 101-104 respectively according to the embodiments 1-4 described above. Here, the description will be given taking the origin position signal detector 101 according to the embodiment 1 as an example.

Specifically, in the embodiment 1, it is basically assumed that the origin position magnetized portion 11 and the side magnetized portions 12 are magnetized with magnetization currents of the same intensity up to saturation magnetic flux density of the magnets. Further, the arrangement and the widths of the side magnetized portions 12 are set based on this assumption. In this respect, it is possible to magnetize each side magnetized portion 12 so as to have magnetic flux density distribution as shown by a dotted line in FIG. 11, for example, by freely controlling the magnetization current of the side magnetized portions 12.

By configuring as described above, it is possible to eliminate a portion extending in the negative direction completely from the magnetic flux density distribution obtained from both the origin position magnetized portion 11 and the side magnetized portions 12 as shown by a dotted line in FIG. 12, thereby making the side peak in an output of an AMR element shown in FIG. 13 completely zero.

### Embodiment 6

An origin position signal detector of an embodiment 6 according to the present invention will be now described with reference to FIG. 14.

A configuration of an origin position signal detector 106 according to the embodiment 6 is basically the same as that of the origin position signal detector 101 according to the embodiment 1, but different in the following points. Specifically, as shown in FIG. 1, in the origin position signal detector 101 according to the embodiment 1, the magnetization direction of the displacement detection magnetized portion 3a and that of the origin position magnetized portion 11 in the incremental track 3 are displaced with respect to the position of the mechanical angle of the rotary drum 20. In contrast, according to the origin position signal detector 106 of the embodiment 6, the magnetization direction of the displacement detection magnetized portion 3a and that of the origin position magnetized portion 11 match with respect to the mechanical angle position in the rotary drum 20. Further, the side magnetized portions 12 that are arranged on both sides of the origin position magnetized portion 11 each have a width “d” of 0.2P, i.e., 0.2λ and are positioned away from the origin position magnetized portion 11 at the magnetization pitch P, that is, via a gap “Q” of λ in the rotational direction 15. Except for the above difference, the configuration of the origin position signal detector 106 is the same as the origin position signal detector 101.

By configuring as described above, although the capability of the origin position signal detector 106 in lowering of the side peak is less good than the origin position signal detector 101 according to the embodiment 1, it is possible to reduce the error in the detection of the angle of the incremental track 3 due to a leakage magnetic flux from the origin position detection track 4 by matching the magnetization directions of the displacement detection magnetized portions 3a and the origin position magnetized portion 11 in the incremental track 3 with respect to the mechanical angle position in the rotary drum 20.

As described above, the embodiment 6 is configured such that the magnetization directions of the displacement detection magnetized portions 3a and the origin position magnetized portion 11 in the incremental track 3 match. However, this embodiment is not limited to the above example. Specifically, the origin position magnetized portion 11 and the side magnetized portions 12 can be disposed relatively with respect to the incremental track 3 by arbitrary magnetization widths and magnetizing positions where an influence of a leakage magnetic flux from the origin position detection track 4 to the incremental track 3 can be reduced or eliminated.

Furthermore, the configuration of the embodiment 6 can also be applied to the embodiments 2-5 described previously, and in each case, the effects described in the respective embodiments 2-5 can be achieved. As one example, FIG. 15 shows an origin position signal detector 107 having the side magnetized portions 12 and 13 are provided on each side of the origin position magnetized portion 11 at two portions, that is, plural portions. Here, each of the side magnetized portions 12 has the width “d” of 0.2P, i.e., 0.2λ and is positioned away from the origin position magnetized portion 11 at the pitch P, i.e., via the gap “Q” of λ in the rotational direction 15. Further, each of the side magnetized portions 13 has a width “e” of 0.1λ and is positioned away from the side magnetized portion 12 via a gap “R” of 0.4λ in the rotational direction 15. Moreover, the configuration of the embodiments 2 and 4 described above can be applied in combination with the configuration of the embodiment 6.

It is to be noted that, by properly combining the arbitrary embodiments of the aforementioned various embodiments, the effects possessed by them can be produced.

Although the present invention has been fully described in connection with the preferred embodiments thereof with reference to the accompanying drawings, it is to be noted that various changes and modifications are apparent to those skilled in the art. Such changes and modifications are to be understood as included within the scope of the present invention as defined by the appended claims unless they depart therefrom.

Further, the disclosure of Japanese Patent Application No. 2008-67536 filed on Mar. 17, 2008 including the specification, the drawings, the scope of the invention, and the abstract is hereby incorporated by reference in its entirety.

### INDUSTRIAL APPLICABILITY

The present invention can be utilized for origin position signal detectors for detecting an origin position in magnetic rotational angle sensors such as magnetic rotary encoders and magnetic position detectors such as magnetic linear encoders.

1. An origin position signal detector comprising: a detection target member which includes an incremental track and an origin position detection track; and a magnetic sensor configured to detect magnetic fields in the incremental track and the origin position detection track, the incremental track having displacement detection magnetized portions magnetized at equal intervals along a displacement direction for detecting a displacement amount, the origin position detection track having an origin position magnetized portion for detecting an origin position for the detection of the displacement amount,
the origin position detection track further including side magnetized portions on both sides of the origin position magnetized portion in the displacement direction, the side magnetized portions being magnetized with magnetization in the same direction as the origin position magnetized portion.

2. The origin position signal detector according to claim 1, wherein
the side magnetized portion is disposed on each side of the origin position magnetized portion with an equal number.

3. The origin position signal detector according to claim 1, wherein
the side magnetized portion is disposed away from the origin position magnetized portion via a specific gap.

4. The origin position signal detector according to claim 1, wherein
the origin position magnetized portion and the side magnetized portions are magnetized with magnetization currents of the same intensity.

5. The origin position signal detector according to claim 1, wherein
the origin position magnetized portion and the side magnetized portions are respectively magnetized with magnetization currents of different intensities.

6. The origin position signal detector according to claim 1, wherein
a magnetization width of each side magnetized portion decreases as a distance from the origin position magnetized portion increases.

7. The origin position signal detector according to claim 1, wherein
the origin position magnetized portion and the side magnetized portions are magnetized at relative positions at which an influence to the magnetization of the incremental track is eliminated.
